(19) United States
(12) Patent Application Publication
(10) Pub. No.: US 2012/0279567 A1
(43) Pub. Date: Nov. 8, 2012

(54) Solar Energy System with Automatic Dehumidification of Electronics

(75) Inventor: William C. Alexander, Spicewood, TX (US)

(73) Assignee: Ideal Power Converters Inc., Spicewood, TX (US)

(21) Appl. No.: 13/401,771

(22) Filed: Feb. 21, 2012

Related U.S. Application Data
(60) Provisional application No. 61/444,365, filed on Feb. 18, 2011.

(51) Int. Cl. H01L 31/0203

(52) U.S. Cl. 136/259

(57) ABSTRACT

Methods and systems for photovoltaic power generation. Humidity control for the electronics in the power converter is provided by a dehumidifier which exploits the breathing of the electronics compartment due to the temperature rise caused when insolation increases at the start of a normal day.

### CROSS-REFERENCE

Priority is claimed from U.S. provisional application 61/444,365, which is hereby incorporated by reference.

### BACKGROUND

The present application relates to green energy, and more particularly to solar energy systems which can provide power to the electric supply network (grid).

Note that the points discussed below may reflect the hindsight gained from the disclosed inventions, and are not necessarily admitted to be prior art.

Solar energy is one of the main forms of environmentally friendly energy. Commercial and government buildings are increasingly including photovoltaic collection panels on unused roof space, and these installations may need to handle a substantial amount of power. The energy density of sunlight at Earth orbit is about 1 kW per square meter, so (even after reduction for the angle of incidence, atmospheric scattering, occlusion, and the inefficiency of the photovoltaic devices) a large building has the potential to generate a megawatt or more of electrical power. This power can be used for at least some of the building's electrical loads (such as air conditioning) to reduce the cost of power bought from the grid which supplies power. However, in many places this power can also be sold back to the electrical power supplier.

The power from a photovoltaic unit will vary in dependence on the amount of sunlight received (“insolation”), and hence is somewhat unpredictable. Power conversion subsystems are used to convert this received power (typically at 600-1000V DC) to values (of voltage, current, frequency, and phase) which are suitable for powering a local load and/or for charging batteries and/or for feeding back into the local power grid.

### BRIEF DESCRIPTION OF THE DRAWINGS

The disclosed inventions will be described with reference to the accompanying drawings, which show important sample embodiments and which are incorporated in the specification hereof by reference, wherein:

FIG. 1 schematically shows an innovative solar energy system, which includes a dehumidifier with no moving parts.

FIG. 2 shows another example of a solar energy system, which includes automatic dehumidification for the electronics.

FIG. 3 schematically shows electrical and airflow connections of a desiccant unit in a sealed compartment for electronics.

FIG. 4 shows an example of physical positioning of the desiccant unit.

### DETAILED DESCRIPTION OF SAMPLE EMBODIMENTS

The numerous innovative teachings of the present application will be described with particular reference to presently preferred embodiments (by way of example, and not of limitation). The present application describes several inventions, and none of the statements below should be taken as limiting the claims generally.

Commonly owned U.S. application Ser. Nos. 13/308,200 and 13/308,356, and PCT applications PCT/US11/62689 and PCT/US11/62710, all of which are hereby incorporated by reference in their entireties for all purposes, describe many details of various preferred implementations.

The present inventor has realized that the possibility of sales back into the grid, and the rapidly declining price of high-capacity batteries, has led to a change in usage which can be advantageously exploited. Since the solar array's power output can be useful regardless of the local demand, the power conversion circuitry (in many installations) is likely to be operated to draw approximately all available power from the photovoltaic elements, approximately all the same. Thus, in addition to random variations due to weather or local demand, the power transfer will have a strong 24-hour frequency component (12 μHz). In particular, it is likely that, on average, the power handled by the conversion circuits will increase dramatically during the first hours after sunrise, as insolation and human activity both increase. Moreover, since no power converter is 100% efficient, it is likely that waste heat from the power conversion circuitry will heat up the interior of whatever enclosure that circuitry is in. Also, ambient temperature (depending on location and weather) will also correlate with insolation.

The present inventor has realized that this daily cycle implies that any compartment which contains the electronics for a large photovoltaic inverter will predictably breathe: unless the compartment is hermetically sealed, the air in the compartment will predictably expand, on typical mornings, when the temperature inside the compartment normally rises. This regular breathing action means that the humidity inside the compartment cannot be isolated from the ambient humidity, and this in turn means that condensation is possible inside the compartment.

Humidity, and especially condensation, are very undesirable in an enclosure with power electronics. In the worst case, leakage currents, component degradation, and/or arcing can occur.

The present application describes solar power systems with a new method of humidity control for the electronics. The daily cycle of activity (and the corresponding pattern of ohmic heating by the power electronics) is used to drive a dehumidifying subsystem which shares an enclosure with power electrical elements. The enclosure does not have to be hermetic, but is allowed to “breathe” as its internal temperature cycles. Preferably the enclosure has only a single port to ambient atmosphere, and all outflow through this port must pass through a humidity absorption element. When gas flow is outbound (e.g. in the morning when insolation is increasing, and power conversion circuits are beginning to transfer significant power), a humidity absorption element is heated to desorb at least some of its moisture content; this moisture content is transported out of the enclosure by the gas outflow. When insolation decreases at the end of the day, and the transferred power (and waste heat) decreases, the humidity absorption element will not be saturated, and can absorb moisture from trapped or inflowing air.

The enclosure is preferably enclosed with a seal against dust and debris, but does not have to be hermetically sealed. This is an advantage, since hermetic enclosures require additional structural strength, are more difficult to access for maintenance, and may themselves be subject to additional certification requirements.

The present application discloses a Sealed Compartment Vent and Dehumidifier which allows air to exit and enter a sealed compartment, maintaining pressure equalization with the ambient environment during temperature changes, while assuring that air entering the compartment is dry. This is done with no moving parts or power semiconductors.

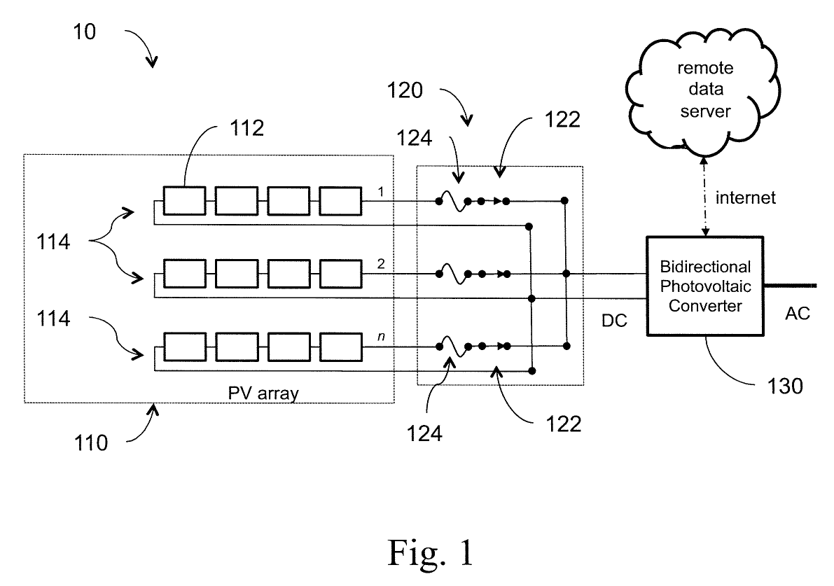

FIG. 1 is an overview of a photovoltaic power system which includes a dehumidification unit (VDD) in the electronics compartment.

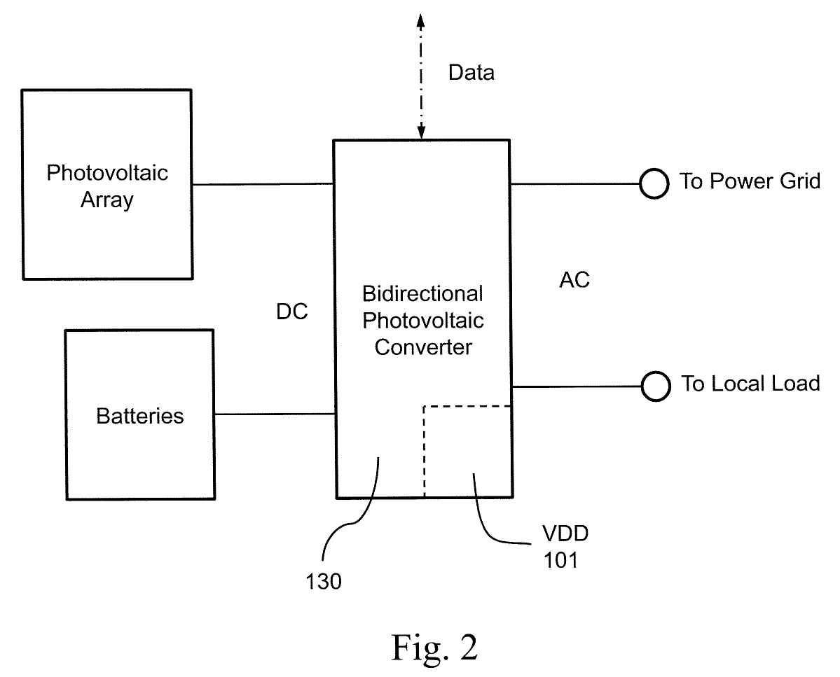

FIG. 2 is another overview of a photovoltaic power system which includes a dehumidification unit (VDD) in the electronics compartment. This system can be the same as the system of FIG. 1, or can be different.

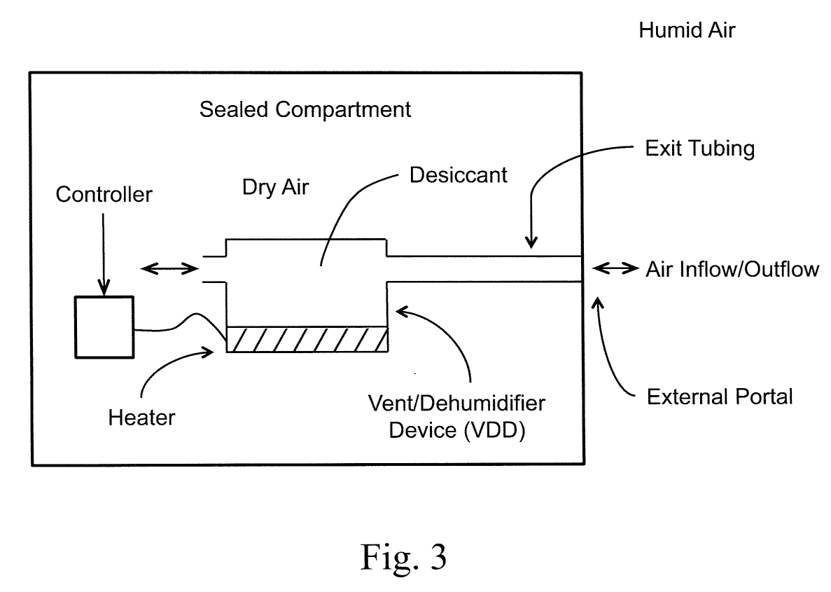

As shown in FIG. 3, this is accomplished by means of a Vent/Dehumidifier Device (VDD) placed within the sealed compartment. The VDD preferably contains any suitable desiccant (e.g. granules of silica gel), and also has an attached electric heater that is selectively activated by an attached controller. The VDD further has two portals, one which is open to the air within the Sealed Compartment, and the other which is attached to an External Portal.

In this example (for a 30 kW inverter), the dimensions of the sealed compartment are about 37 cm×37 cm×18 cm deep. Resistive losses will occur in the power semiconductors, and hysteretic and ohmic losses will occur in the link inductor, even if all switching is perfectly timed. The link inductor itself, in this example, is located in a separate compartment of the unit. Nevertheless, both compartments are thermally coupled through the metal box and the heat sink, so that the compartment which contains the electronics will still see approximately the same temperature rise as the inductor itself. In the example described, the heat sink is selected so that the temperature rise at full power is 15 degrees C.

In this example a thermistor is mounted on the heat sink, so that the control electronics know what the instantaneous temperature is. The measured temperature is tracked over a 15 minute time lag, and when the temperature is found to have risen more than a certain number of degrees within this time lag (e.g. 3 degrees C.), the heater on the desiccant is turned on.

In this example the heater is merely a 5 W unit, and is driven at a low enough voltage that it consumes only a few Watts. This level of drive can be provided by a control voltage output from the control electronics, without any need for high-power drive elements.

Note that the temperature in the Sealed Compartment will also be affected by changes in the ambient, as well as by heat generation internal to the compartment. The resulting rise in temperature causes the air within the compartment to expand, which produces an air flow through the VDD to the External Portal. The controller senses the rise in temperature, or is otherwise somehow made aware of an actual or pending temperature rise, and activates the VDD heater, causing its temperature to rise high enough to drive the water out of the desiccant within the VDD, with the result that both air and water vapor exit through the External Portal. When the controller determines by sensing means or otherwise that the temperature is no longer rising, it disables the VDD heater, allowing the VDD and contained desiccant to cool off. When the temperature inside the compartment drops, the air pressure drops, drawing in air through the External Portal. That air passes through the now dry desiccant, removing the water vapor from the re-entering air, which maintains a dry compartment.

The choice of the desiccant material is not critical. In the example described, a few tens of grams of desiccant has been found sufficient for the 24 liter box in the example above. Alternatively, comparing volume to volume, the volume of desiccant in the example above is slightly more than 0.1% of the sealed compartment's volume.

FIG. 1 schematically shows a photovoltaic (PV) system 10 for collection of solar energy. PV system 10 generally comprises a PV array 110, a string combiner 120, and a converter 130. PV array 110 preferably comprises a plurality of photovoltaic modules 112. A PV module is typically a generally planar device comprising a plurality of PV cells.

Several PV modules 112 are combined in series to form strings 114. Each string 114 preferably comprises between 8 and 15 PV modules 112. However, the number of PV modules 112 in a string 114 can vary depending on the output voltage of each PV module 112 and the desired maximum DC operating voltage of PV system 10. Common maximum DC operating voltages are 600V DC and 1000V DC. Strings 114 are preferably combined in parallel at string combiner 120.

String combiner 120 optionally includes a switch 122 for each string 114 in PV array 110. Switch 122 is configured to selectively connect or disconnect string 114 from PV array 110. Each switch 122 is separately operable, so that one or more switches 122 can be opened (disconnecting one or more string 114 from PV array 110) while other switches 122 remain closed (so that other strings 114 remain connected). String combiner 120 also preferably comprises a fuse 124 for each string 114.

Under normal operating conditions, DC power from string combiner 120 is fed into PV converter 130. PV converter 130 converts the DC power to AC power, which can be used onsite or distributed over an AC distribution system. PV converter 130 is preferably a bidirectional PV converter, such as the PV converter described in WO2008/008143. PV converter 130 can alternatively be operated in reverse, so that PV converter 130 draws power from an AC power distribution system, converts the AC power to DC, and delivers a DC potential to PV array 12. PV converter 130 is preferably configured to be able to provide either a forward potential—that is, a DC voltage tending to induce current in the normal direction of current flow of the PV modules—or a reverse potential, tending to induce a current in the opposite direction of normal current through the PV modules or tending to retard the flow of current in the normal operating direction.

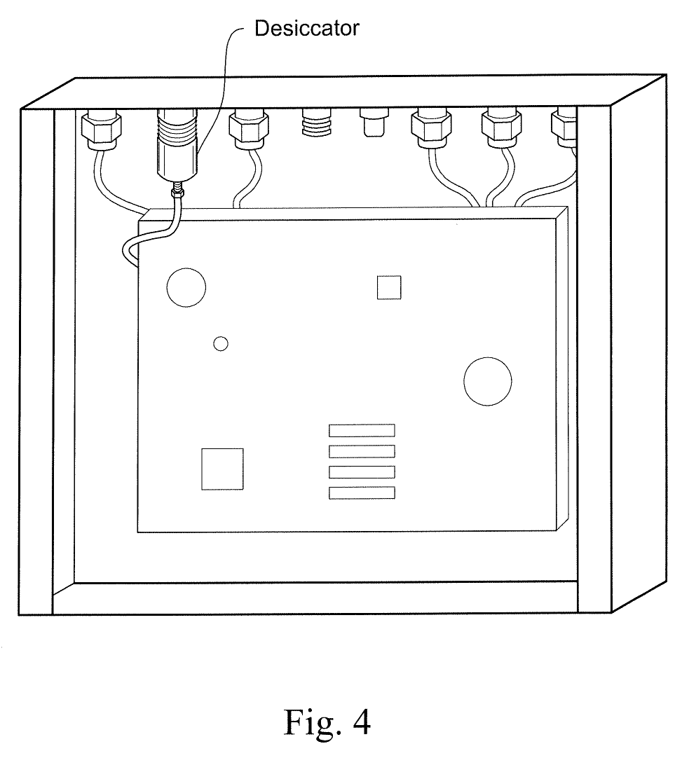

Preferably the desiccant material and the small heater are combined in a single easily-installed module. FIG. 4 gives an idea of the positioning of such a dehumidifier module in a compartment with the electronics. It can be seen that the dehumidifier module is relatively close to the access panel; this makes field replacement of the dehumidifier module easy, if such should ever be needed.

However, the operation of the dehumidifier module is extremely simple, and its lifetime can be expected to be correspondingly long. When temperature rise causes the sealed compartment to “breathe out,” the desiccant material only needs to be heated enough to release some of the water it has absorbed. The temperature cycle which the desiccant experiences does not extend to complete hydration nor to complete dehydration: only part of the hydration/temperature curve is used.

For example, a typical silica gel formulation will dehydrate completely in about two hours at 250 F or higher. However, the adsorption reduces, with rising temperature, at temperatures above 100 F.

In general, most hygroscopic materials will have an equilibrium relation with the relative humidity of the surrounding air: at a given temperature, a certain equilibrium moisture content (“EMC”) in the solid material will correspond to some particular relative humidity (“RH”) in the air. (This relation is often referred to as the “absorption isotherm.”) At higher temperatures (below the temperature where the solid material becomes totally dehydrated), the isotherm shifts: for a given EMC, the corresponding RH will be higher at higher temperature.

This relation helps to understand the disclosed inventions. In the morning, as the power transfer ramps up, the temperature inside the sealed compartment can be as much as 15 degrees C. above ambient temperature (and the ambient temperature itself is likely to be rising). A rise in temperature lowers the relative humidity of the air in the compartment. At the same time, the rise in temperature of the desiccant, which is even greater, raises the relative humidity which the desiccant would be in equilibrium with. The combined effect of these changes is to shift the balance between the desiccant and the humid air, so that the desiccant is more likely to desorb moisture than to adsorb it. In the long term the morning and evening shifts will tend to balance around a point of average equilibrium, so that the dehumidifier has a net effect of moving moisture out of the compartment. This is advantageous.

According to some but not necessarily all embodiments, there is provided: A solar energy system, comprising: a) a photovoltaic energy source which supplies electrical power; b) power conversion circuitry, within an enclosure, which is connected to draw power from said energy source and to supply power to at least one output portal; and c) a dehumidifier which is also located within said enclosure, and which intercepts substantially all airflow through at least one aperture of said enclosure, and which includes desiccant material and at least one heating element; wherein said enclosure is generally sealed, except for one or more of said apertures whose airflow is intercepted by one or more of said dehumidifiers; and wherein said heating element heats said desiccant material selectively, under conditions when insolation and/or expected insolation is increasing.

According to some but not necessarily all embodiments, there is provided: A green energy system, comprising: a) an energy source which supplies electrical power; b) power conversion circuitry, within an enclosure, which is connected to draw power from said energy source and to supply power to at least one output portal; and c) a dehumidifier which is also located within said enclosure, and which intercepts substantially all airflow through at least one aperture of said enclosure, and which includes desiccant material and at least one heating element; wherein said enclosure is generally sealed, except for one or more of said apertures; and wherein said heating element heats said desiccant material selectively, at times when waste heat from said power conversion circuitry is increasing, to desorb moisture from said desiccant. 7. A method of operating a solar energy system, comprising: operating power conversion circuitry, which is located within an enclosure having at least one air passageway to atmosphere, to change the electrical characteristics of power received from a photovoltaic energy source; and when heat dissipated by said power conversion circuitry is increasing at more than threshold rate, activating an electrical heater which is thermally coupled to a desiccant material; wherein said desiccant material, which is heated by said heater, is in contact with every said air passageway.

According to some but not necessarily all embodiments, there is provided: A method of operating a solar energy system, comprising: operating power conversion circuitry, which is located within an enclosure having at least one air passageway to atmosphere, to change the electrical characteristics of power received from a photovoltaic energy source; and when heat dissipated by said power conversion circuitry is increasing at more than threshold rate, activating an electrical heater which is thermally coupled to a desiccant material; wherein said desiccant material, which is heated by said heater, is in contact with every said air passageway.

According to some but not necessarily all embodiments, there is provided: Methods and systems for photovoltaic power generation, wherein humidity control for the electronics in the power converter is provided by a dehumidifier which exploits the breathing of the electronics compartment due to the temperature rise caused when insolation increases at the start of a normal day.

Modifications and Variations

As will be recognized by those skilled in the art, the innovative concepts described in the present application can be modified and varied over a tremendous range of applications, and accordingly the scope of patented subject matter is not limited by any of the specific exemplary teachings given. It is intended to embrace all such alternatives, modifications and variations that fall within the spirit and broad scope of the appended claims.

For example, other conditions can be used for turning on the dehumidifier's heater. For example, the heater can be turned on, even without temperature sensing, by tracking power transfer or current as a proxy. The heater can even be turned on according to time of day, without relying on any sensor inputs at all.

Other conditions can also be used for turning off the dehumidifier's heater. For example, the heater can be turned off after a certain number of seconds of operation, or by tracking power transfer or current as a proxy for temperature rise.

Desiccants which can be used, in various applications, include e.g. silica gel, activated charcoal, montmorillonite clay, and zeolites.

None of the description in the present application should be read as implying that any particular element, step, or function is an essential element which must be included in the claim scope: THE SCOPE OF PATENTED SUBJECT MATTER IS DEFINED ONLY BY THE ALLOWED CLAIMS. Moreover, none of these claims are intended to invoke paragraph six of 35 USC section 112 unless the exact words “means for” are followed by a participle.

The claims as filed are intended to be as comprehensive as possible, and NO subject matter is intentionally relinquished, dedicated, or abandoned.

What is claimed is:

1. A solar energy system, comprising:
a) a photovoltaic energy source which supplies electrical power;
b) power conversion circuitry, within an enclosure, which is connected to draw power from said energy source and to supply power to at least one output portal; and
c) a dehumidifier which is also located within said enclosure, and which intercepts substantially all airflow through at least one aperture of said enclosure, and which includes desiccant material and at least one heating element;
wherein said enclosure is generally sealed, except for one or more of said apertures whose airflow is intercepted by one or more of said dehumidifiers;
and wherein said heating element heats said desiccant material selectively, under conditions when insolation and/or expected insolation is increasing.

2. The system of claim 1, wherein said desiccant material is silica gel.

3. The system of claim 1, wherein said heating element has a power of less than 10 Watts.

4. The system of claim 1, wherein said desiccant material has a dry volume which is more than 0.1% and less than 1% of the volume of said enclosure.

5. The system of claim 1, wherein said desiccant material is silica gel.

6. A green energy system, comprising:
a) an energy source which supplies electrical power;
b) power conversion circuitry, within an enclosure, which is connected to draw power from said energy source and to supply power to at least one output portal; and
c) a dehumidifier which is also located within said enclosure, and which intercepts substantially all airflow through at least one aperture of said enclosure, and which includes desiccant material and at least one heating element;
wherein said enclosure is generally sealed, except for one or more of said apertures;
and wherein said heating element heats said desiccant material selectively, at times when waste heat from said power conversion circuitry is increasing, to desorb moisture from said desiccant.

7. A method of operating a solar energy system, comprising:
operating power conversion circuitry, which is located within an enclosure having at least one air passageway to atmosphere, to change the electrical characteristics of power received from a photovoltaic energy source; and
when heat dissipated by said power conversion circuitry is increasing at more than threshold rate, activating an electrical heater which is thermally coupled to a desiccant material;
wherein said desiccant material, which is heated by said heater, is in contact with every said air passageway.
